(19) United States
(12) Patent Application Publication
(10) Pub. No.: US 2005/0191768 A1
(43) Pub. Date: Sep. 1, 2005

(54) Apparatus and method for measuring substrates

(76) Inventors: Young-Jee Yoon, Gyeonggi-do (KR); Chung-Sam Jun, Gyeonggi-do (KR); Chul-Gi Song, Seoul (KR); Sang-Mun Chon, Gyeonggi-do (KR)

Correspondence Address: MARGER JOHNSON & MCCOLLOM, P.C., 1030 SW MORRISON STREET, PORTLAND, OR, 97205, US

(21) Appl. No.: 11/054,752

(22) Filed: Feb. 9, 2005

(30) Foreign Application Priority Data
Feb. 26, 2004 (KR) 2004-13197

(51) Int. Cl. H01L 21/4763; G01R 31/26; H01L 21/66

(52) U.S. Cl. 438/7; 438/14; 324/765

(57) ABSTRACT

A substrate measuring apparatus includes a reference value storage unit, an electron irradiator, a current measuring device, and a property value calculating device. The reference value storage unit stores data on the relationship between current flow in a sample substrate with a contact hole of known characteristics that is irradiated by an electron beam. The current measuring device measures current flow in a test substrate. The property value calculating device calculates the property value of the contact hole formed in a material layer of the test substrate using the current flow in the test substrate and the data stored in the reference value storage unit. The property values of the contact hole may be a surface area of underlying substrate exposed by a contact hole or an amount of residual material remaining in the contact hole.

### PRIORITY STATEMENT

This application claims the priority of Korean Patent Application No. 2004-13197, filed on Feb. 26, 2004 in the Korean Intellectual Property Office, the disclosure of which is incorporated herein in its entirety by reference.

### BACKGROUND OF THE INVENTION

1. Field of the Invention

The present invention relates to an apparatus and method for measuring substrates and, more particularly, to an apparatus and method for measuring property values of contact holes formed at a material layer on a substrate.

2. Description of Related Art

In fabrication of semiconductor devices, deposition, exposure, and etching processes are repeatedly performed on a semiconductor substrate such as a silicon wafer to form patterns that have the properties of the semiconductor devices. Such semiconductor devices may require an electrical connection of upper and lower conductors with an interlayer dielectric interposed therebetween. The upper and lower conductors are interconnected through a contact hole that penetrates the interlayer dielectric to expose a predetermined region of the lower conductor. A part of the upper conductor or another conductor fills the contact hole, enabling the upper and lower conductors to be electrically interconnected. Using an etch gas, a predetermined region of silicon oxide formed on the silicon substrate is removed to form the contact hole.

It is very important that a contact hole is formed to a predetermined width (area). If an area of a contact hole exposed after an etch process may be smaller than a set value or the etch process is not completely performed, residuals may remain in the contact hole. Thus, an increase in the resistance value causes a bad electrical connection between the upper and lower conductors.

In view of the foregoing, a test process is performed for the contact holes testing whether they are accurately formed. Typically, contact holes are destructively tested by sawing a wafer to check the vertical profile of the wafer. Alternatively, an operator uses a scanning electron microscope (SEM) to visibly determine whether contact holes are accurately formed. The former offers a comparative precision, but wastefully destroys wafers and requires lots of test time. Further, the latter requires lots of test time and results in conspicuously lower test reliability. With recent trends toward greater wafer calibers and finer patterns, the above-mentioned problems become severe.

### SUMMARY OF THE INVENTION

A substrate contact hole measuring apparatus is provided that efficiently measures property values of a contact hole formed in a material layer of a test substrate by irradiating the substrate with an electron beam and measuring current flow in the irradiated substrate. A method of measuring property values of a contact hole in a test substrate is also provided.

One embodiment provides a substrate contact hole measuring apparatus including an electron irradiator, a reference data storage unit, a current measuring device and a property value calculating device. The reference data storage unit stores: (a) reference data of current flow in a sample substrate defining a contact hole of known characteristics formed in a material layer that has been irradiated with an electron beam; and (b) reference data of a property value of the contact hole. The property value calculating device calculates a property value of the contact hole in the test substrate using the measured current flow in the test substrate and the reference data (a) and (b).

The reference data (a) can further include current flow measured in the sample substrate over an elapsed time.

The reference data (b) can include a graphical representation of the current flow in the sample substrate. The reference data (b) can also include a convergence value of the current flow in the sample substrate, an extreme value of the current flow in the sample substrate, and a graphical representation of the current flow in the sample substrate prior to convergence of the current flow.

The reference data (b) can include a surface area of underlying substrate exposed by the contact hole. Further, the calculating device can calculate a surface area of underlying substrate exposed by the contact hole in the test substrate.

The reference data (b) can also include an amount of residual material remaining in the contact hole. Further, the calculating device can calculate an amount of residual material remaining in the contact hole in the test substrate.

The contact holes in the sample substrate and the test substrate can be substantially circular in configuration and the property value of each hole can include a diameter of underlying substrate exposed by each contact hole.

The material layer of the respective test substrate and sample substrate can be a dielectric layer. Further, the material layer can be made from a material comprising at least one of silicon oxide (SiO₂), silicon nitride (SiN), aluminum oxide (Al₂O₃), hafnium oxide (HfO₂).

A further embodiment includes a scanning electron microscope that measures an inlet area of the contact hole in the test substrate and a comparator that compares the measured inlet area of the contact hole in the test substrate with the calculated surface area of underlying substrate exposed by the contact hole in the test substrate.

Another further embodiment includes an estimated area storage unit that stores an estimated surface area of underlying substrate to be exposed by the contact hole in the test substrate, and a comparator that compares the estimated area with the calculated surface area of underlying substrate exposed by the contact hole in the test substrate.

Another further embodiment includes a scanning electron microscope that measures an average inlet area of a plurality of contact holes in a test area of the test. The average inlet area is calculated by dividing a sum of the inlet areas of each of the plurality of contact holes by the number of contact holes. The reference data storage unit further stores a reference value (c) of an average surface area of underlying substrate exposed by a contact hole in the sample substrate.

Another embodiment provides a test substrate contact hole measuring apparatus that includes an electron irradiator, a reference data storage unit, a current measuring device, a contact hole property value calculating device, a scanning electron microscope (SEM) and a comparator that compares an inlet area of the contact hole in the test substrate measured by the SEM with a calculated surface area of underlying substrate exposed by the contact hole in the test substrate.

Yet another embodiment provides a test substrate contact hole measuring apparatus that includes an electron irradiator, a reference data storage unit, a current measuring device, a contact hole property value calculating device, an estimate area storage unit which stores an estimate surface area of underlying substrate to be exposed by the contact hole in the test substrate, and a comparator that compares the estimate area with a calculated surface area of underlying substrate exposed by the contact hole in the test substrate.

Yet another embodiment provides a method of measuring a property value of a contact hole formed in a material layer of a test substrate. The method includes irradiating electrons to a sample substrate defining a contact hole of known characteristics formed in a material layer, measuring current flow in the sample substrate, and storing (a) reference data comprising the measured current flow in the sample substrate, and (b) reference data comprising a property value of the contact hole. The method further includes irradiating electrons to the test substrate, measuring current flow in the test substrate, and calculating a property value of the contact hole in the test substrate based on the measured current flow in the test substrate and the reference data (a) and (b). The calculated property value includes a surface area of underlying substrate exposed by the contact hole in the test substrate.

Measuring the current flow in the sample substrate can include measuring the current flow over an elapsed time.

The reference data (b) can include to a graphical representation of the current flow in the sample substrate. The reference data (b) can also include a convergence value of the current flow in the sample substrate, an extreme value of the current flow in the sample substrate, and a graphical representation of the current flow in the sample substrate prior to convergence of current flow.

The reference data (b) can include a diameter of underlying substrate exposed by the contact hole in the sample substrate. Further, the calculated property value can include a diameter of underlying substrate exposed by the contact hole in the test substrate.

A further embodiment of the method includes measuring an inlet area of the contact hole in the test substrate with a scanning electron microscope and comparing the inlet area of the contact hole with the calculated surface area of underlying substrate exposed by the contact hole in the test substrate.

Another further embodiment of the method includes irradiating electrons to an area of the sample substrate defined by a plurality of contact holes and storing reference data (c) comprising an average surface area of underlying substrate exposed per contact hole in the irradiated area of the sample substrate. The further embodiment includes irradiating a test area of the test substrate defined by a plurality of contact holes, scanning the test area with a scanning electron microscope, measuring the sum of surface areas of underlying substrate exposed by the plurality of contact holes, and calculating an average surface area of underlying substrate exposed per contact hole in the test area by dividing the sum of exposed surface areas by the number of contact holes in the test area.

Another further embodiment includes comparing an estimated surface area of underlying substrate to be exposed by a contact hole in the test substrate with the calculated surface area exposed by the contact hole in the test substrate.

### BRIEF DESCRIPTION OF THE DRAWINGS

FIG. 1 illustrates a substrate measuring apparatus according to an embodiment of the present invention.

FIG. 2 illustrates the flow of electrons at a substrate when they are irradiated to the substrate.

FIG. 3 illustrates current flowing at a substrate when an accelerating voltage and a thickness of a dielectric layer are varied.

FIG. 4A and FIG. 4B illustrate currents flowing at a substrate when an accelerating voltage and a kind of a dielectric layer are varied.

FIG. 5A and FIG. 5B illustrate currents flowing at a substrate when an accelerating voltage is varied and when upper and lower dielectric layers constituting a multi-layered structure are varied in thickness.

FIG. 6 illustrates values corresponding to property values of contact holes on a graph of current measured at a substrate.

FIG. 7 illustrates an exemplary method for obtaining property values of contact holes of a test substrate, based on data stored in a reference value storage unit.

FIG. 8 illustrates an example of a substrate measuring apparatus for determining whether an etch process is properly conducted.

FIG. 9 illustrates another example of a substrate measuring apparatus for determining whether an etch process is properly conducted.

FIG. 10A and FIG. 10B illustrates the cases that an etch process for forming a contact hole is properly performed and improperly performed, respectively.

FIG. 11 illustrates a substrate plan image obtained using a scanning electron microscope (SEM).

FIG. 12 is a flowchart of a substrate measuring method according to one embodiment of the present invention.

### DETAILED DESCRIPTION OF THE PREFERRED EMBODIMENTS

The present invention will now be described more fully hereinafter with reference to the accompanying drawings, in which preferred embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the height of layers and regions are exaggerated for clarity.

In this embodiment, a substrate may be a silicon substrate or a substrate on which predetermined layers are deposited. The deposited material layers may be dielectric layers made of, for example, silicon oxide (SiO₂), silicon nitride (SiN), silicon oxynitride (SiON), aluminum oxide (Al₂O₃), hafnium oxide (HfO₂), and combinations thereof. A substrate measuring apparatus measures property values of contact holes formed at a material layer on a semiconductor substrate and uses the measured property values to test whether an etch process for forming contact holes has been performed properly. The property value of the contact holes are values which have an effect on the resistance value when electrically connecting upper and lower conductors of a material layer through contact holes filled with conductor.

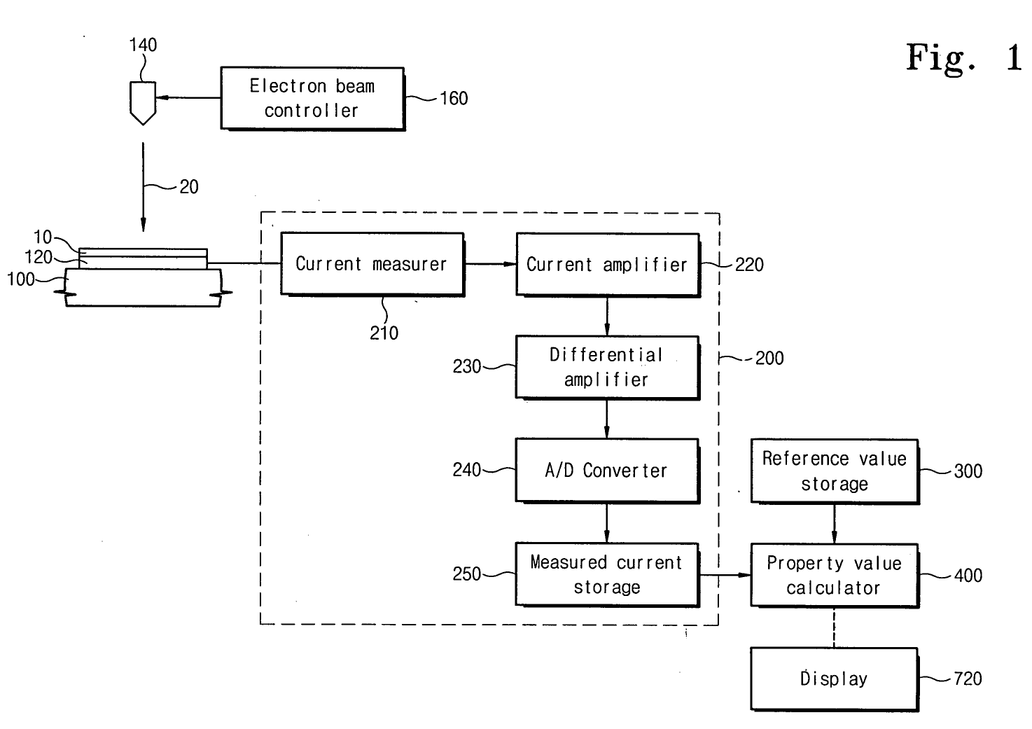

As illustrated in FIG. 1, a substrate measuring apparatus according to one embodiment of the present invention includes a stage 100, an electron irradiator 140, a current measuring device 200, a reference value storage unit 300, and a property value calculator 400. A substrate 10, which is being measured, is placed on the stage 100. An electrode 120 may be interposed between the stage 100 and the substrate 10. The electron irradiator 140 is an electron beam irradiation apparatus for producing an electron beam 20 that irradiates electrons to a predetermined region on the substrate 10. The electron irradiator 140 accelerates the electron beam 20 and irradiates the accelerated electron beam 20 to the substrate 10. In this embodiment, the electron beam 20 is irradiated to a cell area where a pattern is formed, so as to directly measure the substrate 10 at the cell area. Hereinafter, an electron-irradiated area on the substrate 10 is referred to as a test area. An electron beam controller 160 moves the electron irradiator 140 to irradiate electrons to an entire test area on the substrate 10. An electron beam irradiation apparatus has widely been used and will not be described in further detail. The electron irradiator 140 creates electrons using, for example, an MTM cathode or a rope nanotube and irradiates the electrons to the substrate 10.

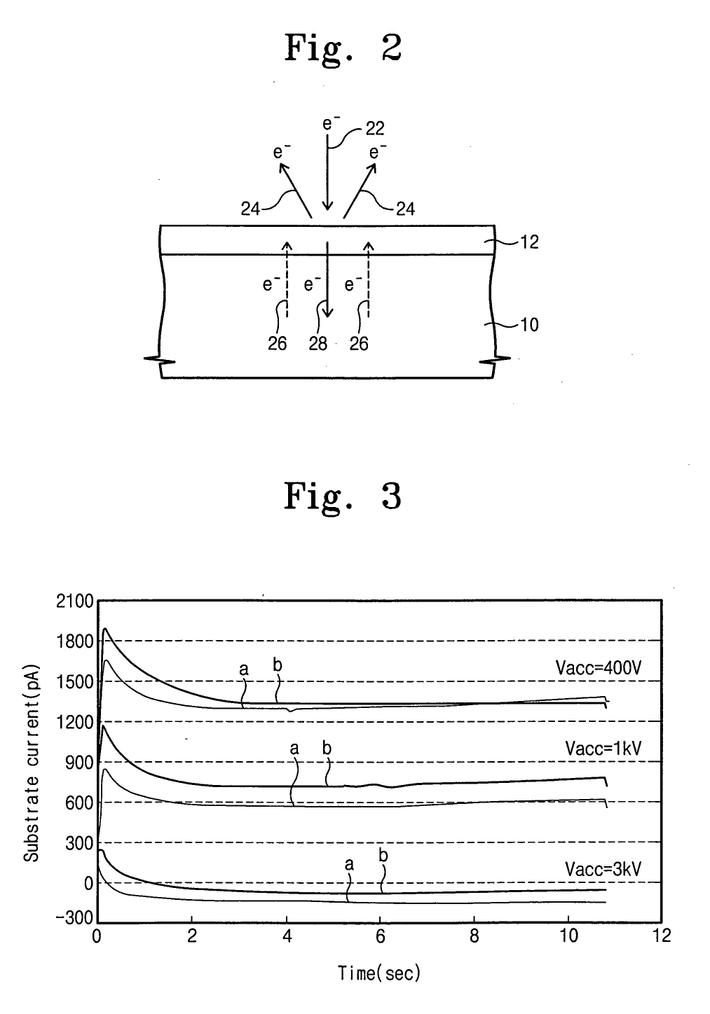

Referring to FIG. 2, if electrons are irradiated to the substrate 10, secondary electrons 24 are released from a dielectric layer 12 deposited on the substrate 10. Electrons 26 flow from the substrate 10 to compensate for the released secondary electrons 24. Partial electrons 28 irradiated from an electron irradiator 140 flow to the substrate 10. Migration of the electrons 26 and 28 in the substrate 10 enables current to flow at the substrate 10. A current measuring device 200 measures current flowing at the substrate 10. Specifically, the current measuring device 200 measures current which continuously flows to the substrate 10 since electrons are irradiated.

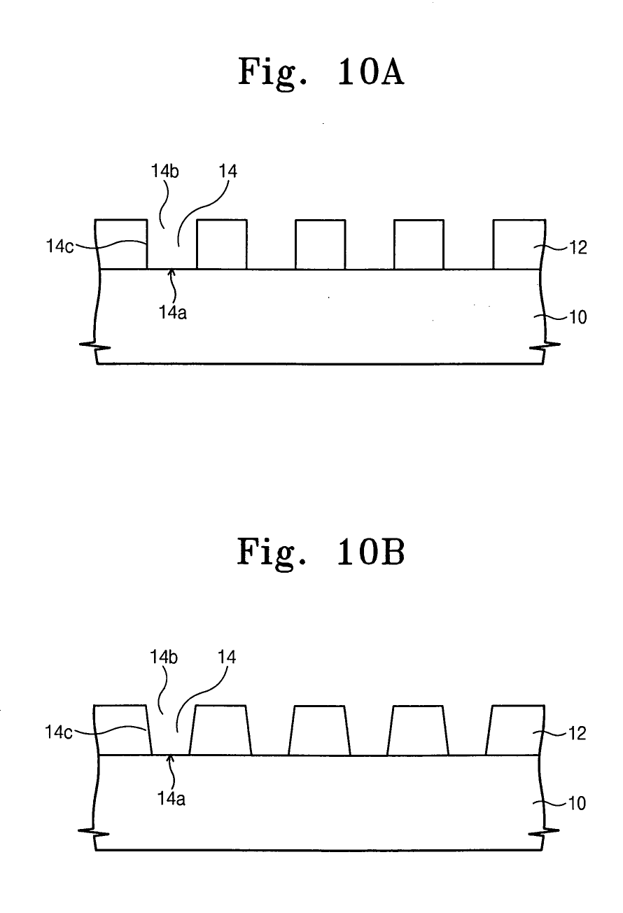

Current flowing to the substrate 10 is affected by various factors such as, for example, the type of a dielectric layer 12 formed on the substrate 10, the thickness of the dielectric layer 12, constituent of ions contained in the dielectric layer 12, the thickness of respective layers constituting a multi-layered structure if the dielectric layer 12 is multi-layered, the substrate area (14a of FIG. 10A) exposed by a contact hole (14 of FIG. 10A) formed at the dielectric layer 12 (hereinafter, the exposed substrate area being referred to as an “exposure area”), the fact whether material remains in the contact hole 14 and the thickness of that material, and an accelerating voltage for accelerating electrons at the electron irradiator 140. Namely, these factors vary the value of current flowing at the substrate 10.

FIG. 3 through FIG. 5 are graphs showing current flow based on elapsed time under various conditions. FIG. 3 illustrates current flowing at a substrate when the accelerating voltage and the thickness of a dielectric layer are varied, in which the substrate is a silicon substrate and the dielectric layer is made of silicon oxide. In the graph of FIG. 3, current values measured in the cases where the thickness of the dielectric layer is 33 angstroms (curve “a”) and 75 angstroms (curve “b”), and an accelerating voltage is 400 volts and 3 kilovolts, respectively. As illustrated in FIG. 3, the magnitude and direction of current flowing at the substrate 10 varies with the magnitude of the accelerating voltage, and the magnitude of the current varies with the thickness of dielectric layer 12.

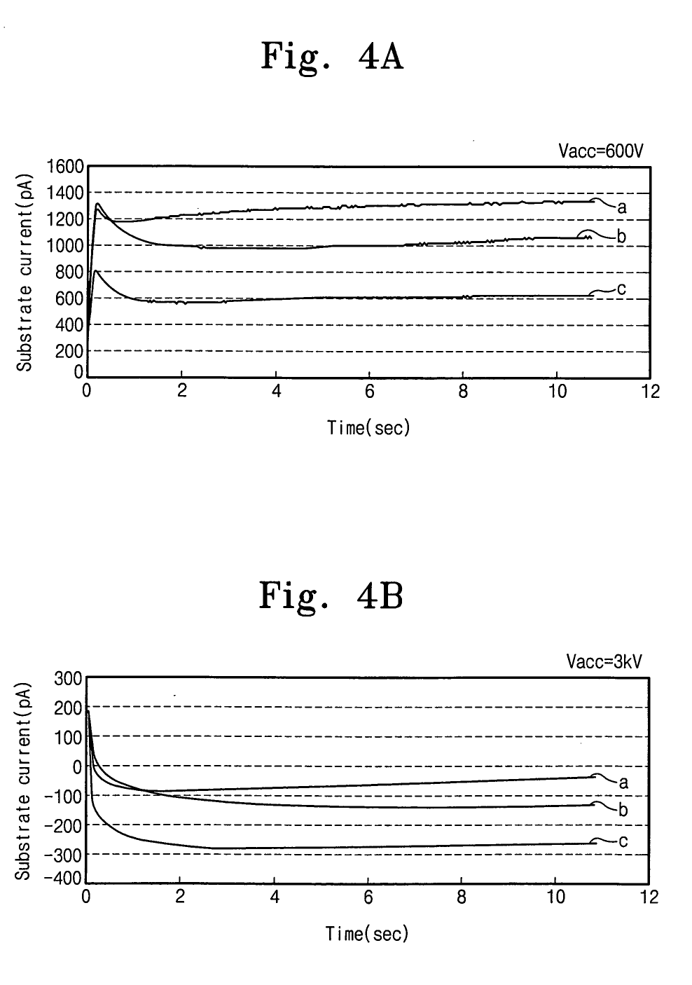

FIG. 4A and FIG. 4B illustrate current flowing at a substrate when the accelerating voltage and the type of dielectric layer are varied. Graphs of FIG. 4A and FIG. 4B illustrate current values measured in the cases that a dielectric layer deposited on a silicon substrate is made of aluminum oxide (Al₂O₃; curve “a”), silicon oxide (SiO₂; curve “b”), and hafnium oxide (HfO₂; curve “c”), respectively. An accelerating voltage of FIG. 4A is 600 volts, and an accelerating voltage of FIG. 4B is 3 kilovolts. As illustrated in FIG. 4A and FIG. 4B, magnitudes of currents flowing at a substrate vary with the type of dielectric layers, and current values vary with fluctuation of accelerating voltages relative to the respective dielectric layers.

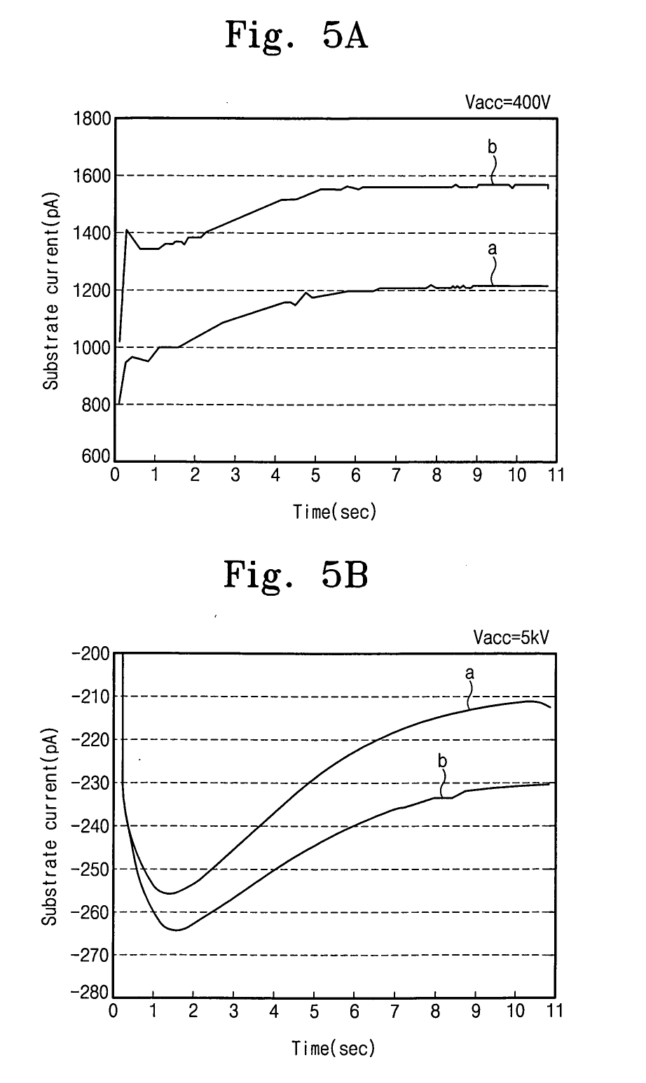

FIG. 5A and FIG. 5B illustrate current flowing at a substrate when the accelerating voltage is varied and when upper and lower dielectric layers constituting a multi-layered structure are varied in thickness. Graphs of FIG. 5A and FIG. 5B illustrate current values of the silicon substrate 10, which are measured in the cases that the dielectric layer 12 deposited on the substrate comprises aluminum oxide (Al₂O₃) of 40 angstroms and hafnium oxide (HfO₂) of 25 angstroms (curve “b”) and comprises aluminum oxide (Al₂O₃) of 28 angstroms and hafnium oxide (HfO₂) of 25 angstroms (curve “a”). The accelerating voltage of FIG. 5A is 400 volts, and the accelerating voltage of FIG. 5B is 5 kilovolts. As illustrated in FIG. 5A and FIG. 5B, values of current flowing at the substrate 10 vary with the thickness of layers which constitutes the dielectric layer 12, and values of currents flowing at the substrate 10 also vary with the accelerating voltage in the case that thicknesses of layers constituting a multi-layered structure are equal to each other. A curve shape of the current value based on time prior to convergence of the current value is called a fluctuation curve. The fluctuation rate varies with the magnitude of the accelerating voltage, a property value of a contact hole 14, and the type of dielectric layer 12. In many cases, a graph of the current value has an extreme value (minimum value) prior to convergence.

Returning to FIG. 1, the current measuring part 200 includes a current measurer 210, a current amplifier 220, a differential amplifier 230, an analog-to-digital converter (A/D converter) 240, and a measured current storage 250. The current measurer 210 measures values of currents flowing at a substrate. The measured current values are amplified by the current amplifier 220. The differential amplifier 230 may be used to eliminate an offset caused by current leaked from the dielectric layer while the current values are amplified by the current amplifier 220. The amplified current is converted to a digital signal by the A/D converter 240 to be stored in the measured current storage 250.

The reference value storage unit 300 stores data on the relationship between property values of a contact hole formed at a material layer on a substrate and values of current flowing at the substrate. In order to obtain data, substrates with a known contact hole in a dielectric layer are extracted as samples. The substrates extracted as samples will be referred to as sample substrates, and to-be-tested substrates will be referred to as test substrates. Further, a contact hole formed in the dielectric layer deposited on a sample substrate will be referred to as a contact hole of a sample substrate, and a contact hole (14 of FIG. 10) formed in the dielectric layer 12 deposited on the test substrate 10 will be referred to as a known contact hole of a test substrate. In order to obtain data stored in the reference value storage unit 300, electrons are irradiated to a sample substrate from the electron irradiator 140 and the value of current flowing at the sample substrate is measured. A property value of the contact hole of the sample substrate is measured using various ways. The property values of the contact hole of the sample substrate and the value of the current flowing at the sample substrate during the irradiation are stored in the reference value storage unit 300. Among current values stored in the reference value storage unit 300, the most conspicuously distinguished accelerating voltage is preferably extracted to be set as an accelerating voltage during the irradiation.

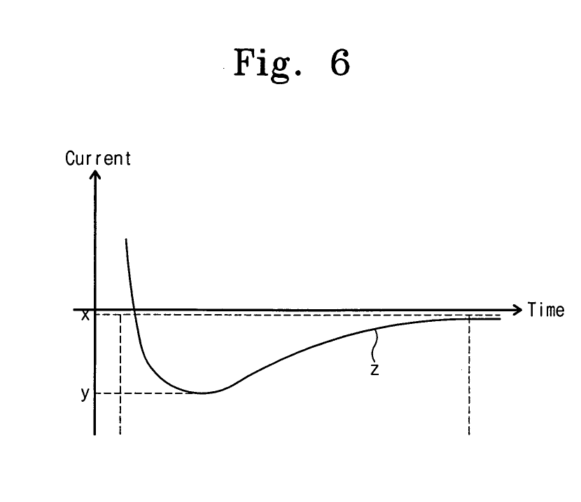

As previously stated, property values of a contact hole have an effect on the resistance value when an upper layer and a lower layer of a material layer are electrically connected by the contact hole and may be an area of the substrate exposed by the contact hole or a thickness of material left in the contact hole. The property values correspond to graph shapes as a function of current values based on time, respectively. FIG. 6 illustrates property values of contact holes on a graph of current measured at a substrate. The property values may be current values measured over elapsed time. In an exemplary embodiment, the property value of the contact hole corresponds to a combination of a convergence value, an extreme value, and fluctuation shapes. For example, if x, y, and z represent a convergence value of current, an extreme value, and a fluctuation shape, respectively, and fₐ and fₜ represent an exposed area of a substrate and a thickness of a material left in the contact hole, respectively, their relationships are expressed as the following equations 1 and 2.
fₐ=fₐ(x,y,z) [Equations 1]
fₜ=fₜ(x,y,z) [Equations 2]

Preferably, the current value stored in the reference value storage unit 300 is an average current value obtained by dividing the current magnitude measured at a reference substrate by the number of contact holes formed in a test area. In the case where the current value is an average current value, data stored in the reference value storage unit 300 may be used even though a test area of a sample substrate is different from a test area of a test substrate 10. If xₐᵥ, yₐᵥ, and zₐᵥ represent a convergence value, an extreme value, and a fluctuation shape in the average current value, respectively, and fₐ and fₜ represent an exposed area of a substrate and a thickness of material left in the contact hole, respectively, their relationships are expressed as the following equations 3 and 4.
fₐ=fₐ(xₐᵥ,yₐᵥ,zₐᵥ) [Equations 3]
fₜ=fₜ(xₐᵥ,yₐᵥ,zₐᵥ) [Equations 4]

The property value calculator 400 calculates the property value of a contact hole of the test substrate 10 based on the data stored in the reference value storage unit 300 and the current values measured at the test substrate. The property value calculator 400 receives the current value of the test substrate 10 from the measured current storage 250 and combines the convergence value, the extremum, and the fluctuation shape in the current values of the test substrate 100 to extract the same or similar current value from the reference value storage unit 300. Thereafter, the property value calculator 400 searches a contact hole property value corresponding to the extracted value to determine the corresponding property value as a contact hole property value of the test substrate 10. If there is no same or similar current value in the reference value storage unit 300, the property value calculator 400 extracts current values, which are adjacent to the current value of the test substrate and are most similar in fluctuation curve, from the reference value storage unit 300 and extracts contact hole property values each corresponding thereto. The property value calculator 400 compares the current value of the test substrate 10 with the current value extracted from the reference value storage unit 300 to infer a contact hole property value of the test substrate 10 from the contact property values extracted from the reference value storage unit 300.

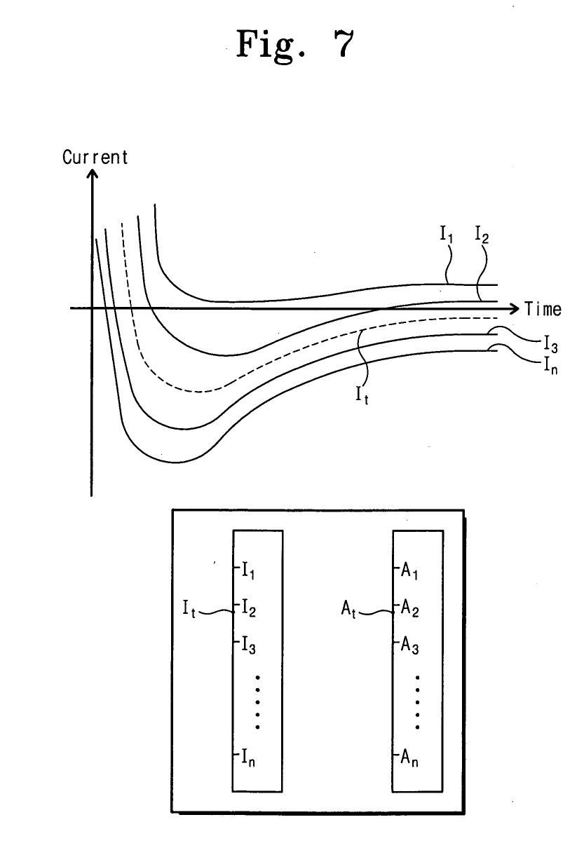

FIG. 7 illustrates a method of obtaining the contact hole property value of test substrate 10 in the case where the same data as the current value of the test substrate 10 does not exist in the reference value storage unit 300. In FIG. 7, Iₜ represents a current value of a test substrate and I₁, I₂, I₃, . . . , Iₙ, . . . represent current values stored in the reference value storage unit 300. Further, A₁, A₂, A₃, . . . , Aₙ, . . . represent exposed areas each corresponding to the current values. Current values I₂ and I₃, which are closest to the current value of the test substrate 10 and are similar in fluctuation curve, are extracted and the exposed areas A₂ and A₃ corresponding to the extracted current values are obtained. Considering the distance rate of I₂, I₃, and Iₜ, an exposed area Aₜ of a test substrate is inferred from the exposed areas A₂ and A₃. The current value of the test substrate 10 and the contact hole property value thereof may be displayed on a display 720.

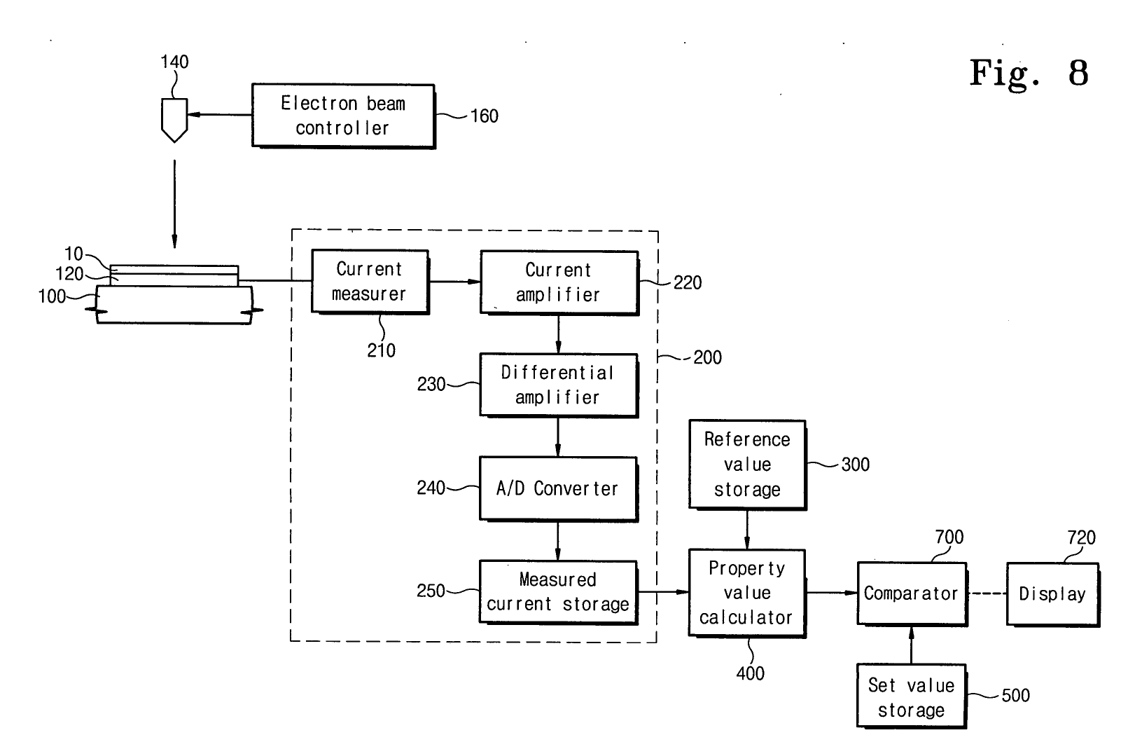

The contact hole property value of the test substrate may be used to determine whether the etch forming contact holes was conducted properly. FIG. 8 illustrates an example of a substrate measuring apparatus for determining whether the etch was conducted properly. Referring to FIG. 8, the measuring apparatus includes an electron irradiator 140, a current measurer 200, a measured current storage 250, a reference value storage unit 300, a property value calculator 400, a preset value storage unit 500, and a comparator 700. The preset value storage unit 500 stores set values of contact hole property values of a test substrate 10 to be formed by an etch process. The contact hole property values stored in the preset value storage unit 500 may be an exposed area of a substrate to be exposed by a contact hole. The comparator 700 compares the set value of an exposed area with the exposed area of the test substrate 10 from the property value calculator 400. The preset value of the exposed area and the exposed area of the test substrate 10 may be displayed on display 720. If a difference between the preset value of the exposed area and the exposed area of the test substrate 10 is within an effective range, the comparator 700 determines that the etch forming the contact holes was conducted properly. If the difference is outside of the effective range, the comparator 700 determines that the etch process was conducted improperly. The determination result may be displayed on the display 720. In the even that the comparator 700 determines that the etch process was conducted improperly, a warning tone is sent or an error message is displayed on the display 720.

The contact hole property values of the test substrate may be used to obtain a profile for the shape of a contact hole. Generally, it is desirable that a lateral face of a contact hole be formed vertically. The profile may include a ratio of an inlet area (14b of FIG. 10) of a contact hole to an exposed area (14a of FIG. 10) thereof and an inclination of a lateral face (14c of FIG. 10) of the contact hole.

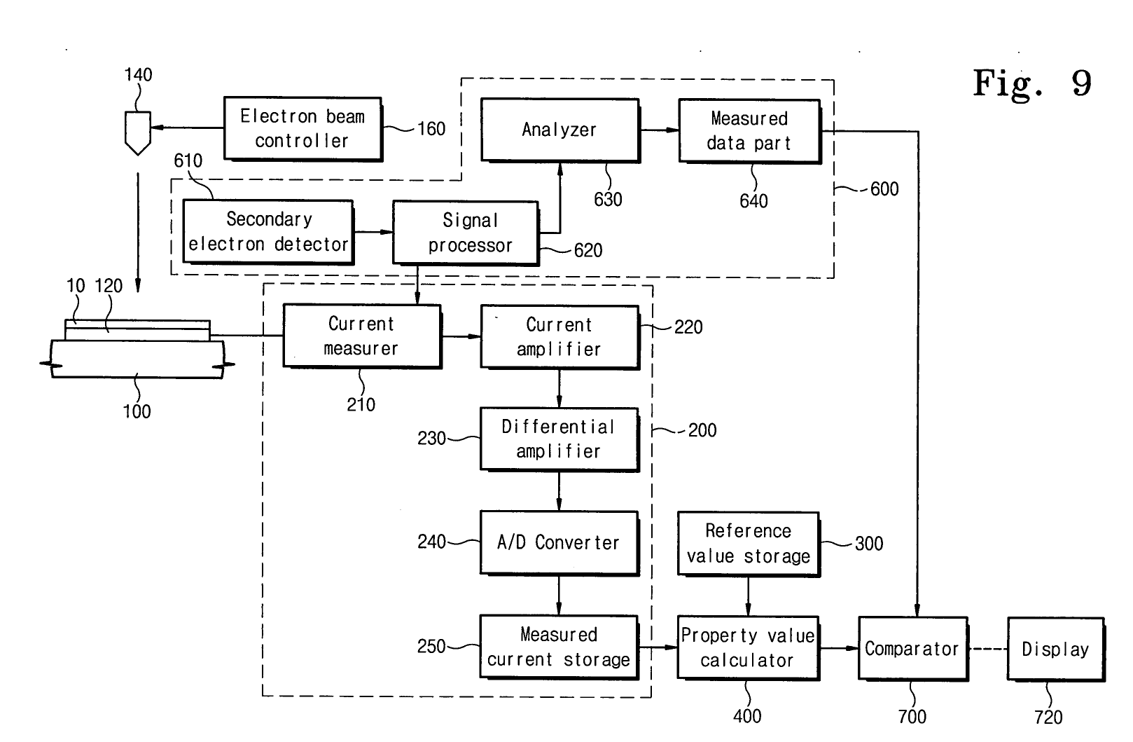

FIG. 9 illustrates a measuring apparatus for obtaining a profile for the shape of a contact hole. FIG. 10A and FIG. 10B illustrates the cases that an etch process for forming a contact hole is performed properly and performed improperly, respectively. Referring to FIG. 9, the measuring apparatus includes a stage 100, an electron irradiator 140, a current measurer 200, a measured current storage 250, a reference value storage unit 300, a property value calculator 400, which are illustrated in FIG. 1, as well as a scanning electron microscope (SEM) 600 and a comparator 700. The SEM 600 measures an inlet area 14b of a contact hole and has a secondary electron detector 610, a signal processor 620, an analyzer 630, and a measured data part 600. The secondary electron detector 610 detects secondary electrons 24 released by irradiation of an electron beam from the surface of dielectric layer 12 formed on test substrate 10. The signal processor 620 converts an analog picture signal, which is composed of electrons detected by the secondary electron detector 610, to a digital signal. The signal processor 620 amplifies the digital signal and transmits the amplified signal to the analyzer 630.

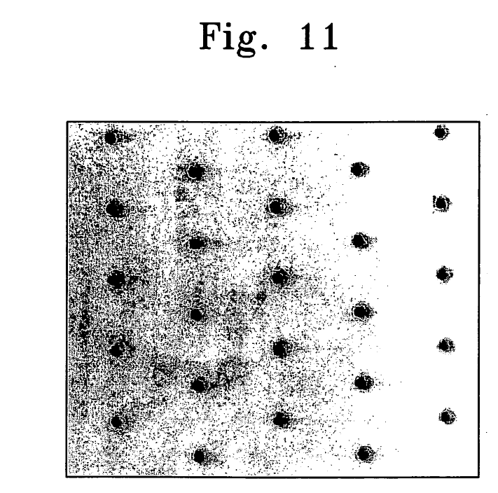

The analyzer 630 obtains an inlet area 14b of each contact hole in a test area. FIG. 11 illustrates a plan image of a test substrate, which is obtained by scanning electron microscope 600. The test area is divided into a plurality of pixels having the same size, and the analyzer 630 detects the number of pixels that an inlet of the contact hole 14 occupies. A total area occupied by the inlet of each contact hole 14 may be calculated using the number of detected pixels to the number of total pixels. The total sum of the inlet areas 14b is divided by the number of the contact holes 14 formed at the test area to calculate an average inlet area relative to a contact hole. The calculated average inlet area is stored in a measured data part 640.

The comparator 700 compares the inlet area 14b of the contact hole stored in the measured data part 640 with the exposed area 14a of the test substrate 10. As illustrated in FIG. 10A, it is desirable that an inlet area of a contact hole is equal to an exposed area 14a of test substrate 10. However, an inlet area 14b of a contact hole is generally larger than the exposed area 14a of the test substrate, as illustrated in FIG. 10B. If a difference between an inlet area 14b of a contact hole and an exposed area 14a of a test substrate is within an effective range, the comparator 700 determines that an etch process for forming contact holes was conducted properly. If the difference is outside of the effective range, the comparator 700 determines that the etch was conducted improperly. The inlet area of the contact hole, the exposed area 14a of the test substrate, and the determination result obtained by the comparator 700 may be displayed on the display 720. In the event that the comparator 700 determines that the etch was conducted improperly, a warning tone is sent or an error message is displayed on the display 720.

The SEM 600 may measure an area of a contact hole at a specific height in the contact hole (e.g., an intermediate spot on the lateral face of the contact hole). A shape of the lateral face (14c) of the contact hole may be inferred from an inlet area, an exposed area, and areas of contact holes measured at a specific height.

In this embodiment, a value of current flowing at the test substrate 10 is measured to calculate the exposed area 14a, and the inlet area 14b of the contact hole is measured using the SEM 600. Therefore, the present invention may be applied to a substrate where a circular contact hole is formed as well as substrates where various shaped contact holes are formed. Although an exposed area is an example of a contact hole property value in this embodiment, the property value may be indicated as a diameter (linewidth) in the case of a circular contact hole.

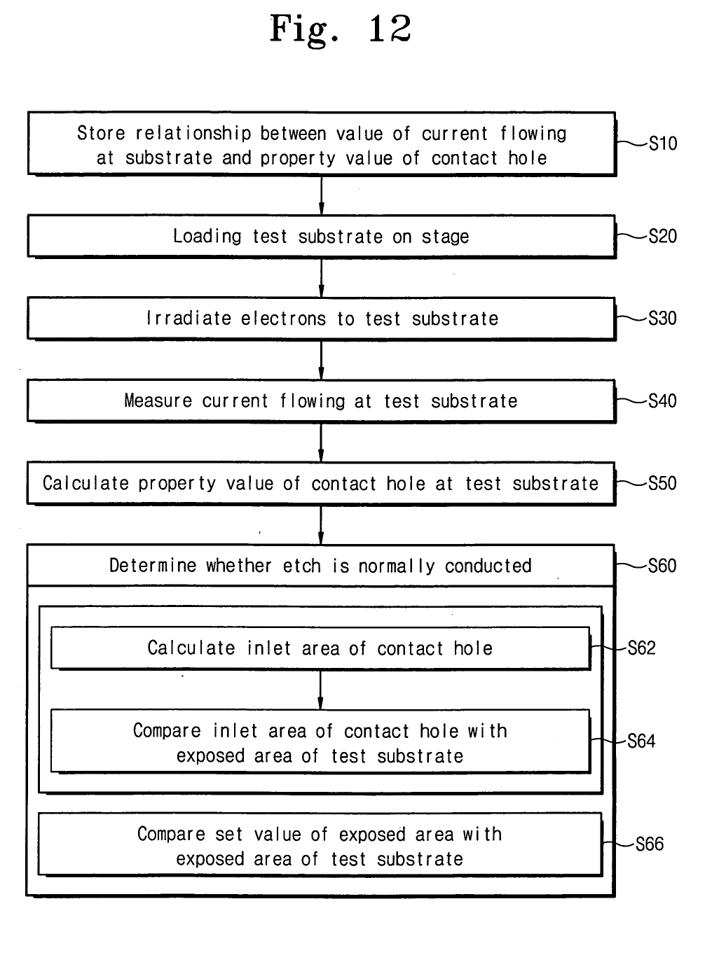

FIG. 12 is a flowchart of a substrate measuring method according to an embodiment of the present invention. Referring to FIG. 12, an electron beam is irradiated to a sample substrate to measure data on the relationship between a value of current flowing at the sample substrate and a property value of a contact hole formed in the dielectric layer on the sample substrate. The data are stored in a reference value storage unit 300 in step S10. The test substrate 10 is placed on stage 100, and electrons are irradiated to the test substrate 10 from electron irradiator 140 in steps S20 and S30. Current flowing at the test substrate 10 is measured by current measuring device 200 in Step S40. A property value calculator 400 calculates a current value, which is similar to a current value of the test substrate 10, from the data stored in the reference value storage unit 300 and a property value corresponding to the extracted current value and recognizes the property value as a contact hole property of the test substrate 10 in step S50.

It is determined in step S60 from the contact hole property value of the test substrate 10, whether an etch process for forming contact holes was conducted properly. In an exemplary embodiment, a scanning electron microscope (SEM) 600 measures at step S62 an inlet area 14b of the contact hole of the test substrate 10 from secondary electrons released from a surface of dielectric layer 12 formed at the test substrate 10 during irradiation of electron beam, and a comparator 700 compares an exposed area 14 at step S64, among the contact hole property values of the test substrate 10, with the inlet area 14b of the contact hole.

In another exemplary embodiment, at step S66 a set value of an exposed area 14a to be exposed by a contact hole at a test substrate 10 is stored in a set value storage 500, and a comparator 700 compares a set value of the exposed area 14a with an exposed area of the contact hole of the test substrate 10.

According to an embodiment of the present invention, it is possible to easily measure contact hole property values such as an area of a substrate exposed by a contact hole or a thickness of material remaining in the contact hole. Further, it is possible to easily determine whether an etch process for forming contact holes was conducted properly.

Although the present invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

1. A substrate contact hole measuring apparatus, comprising:
an electron irradiator for irradiating an electron beam onto a test substrate defining a contact hole formed in a material layer;
a reference data storage unit adapted to store (a) reference data that comprises current flow in a sample substrate defining a contact hole of known characteristics formed in a material layer that has been irradiated with an electron beam, and (b) reference data that comprises a property value of the contact hole;
a current measuring device adapted to measure current flow in the test substrate; and
a calculating device adapted to calculate a property value of the contact hole in the test substrate using the measured current flow in the test substrate and the reference data (a) and (b) from the sample substrate.

2. The apparatus of claim 1, wherein the reference data (a) includes a current flow measured over an elapsed time.

3. The apparatus of claim 2, wherein the reference data (b) includes a graphical representation of the current flow in the sample substrate.

4. The apparatus of claim 2, wherein the reference data (b) includes a convergence value of the current flow in the sample substrate, an extreme value of the current flow in the sample substrate, and a graphical representation of the current flow in the sample substrate prior to convergence of the current flow.

5. The apparatus of claim 1, wherein the reference data (b) includes a surface area of underlying substrate exposed by the contact hole, and wherein the calculating device calculates a surface area of underlying substrate exposed by the contact hole in the test substrate.

6. The apparatus of claim 1, wherein the reference data (b) includes an amount of residual material remaining in the contact hole, and wherein the calculating device calculates an amount of residual material remaining in the contact hole in the test substrate.

7. The apparatus of claim 5, further comprising:
a scanning electron microscope (SEM) for measuring an inlet area of the contact hole in the test substrate; and
a comparator adapted to compare the inlet area of the contact hole in the test substrate with the calculated surface area of underlying substrate exposed by the contact hole in the test substrate.

8. The apparatus of claim 5, further comprising:
an estimated area storage unit adapted to store an estimated area of a surface of underlying substrate exposed by the contact hole in the test substrate; and
a comparator adapted to compare the estimated area with the calculated surface area of underlying substrate exposed by the contact hole in the test substrate.

9. The apparatus of claim 1, further comprising a scanning electron microscope (SEM) for measuring an inlet area of a contact hole in the test substrate,
the electron irradiator for irradiating a test area of the test substrate, the test area defined by a plurality of contacts holes,
the SEM for calculating an average inlet area of a contact hole in the test area by dividing a sum of the inlet areas of each of the plurality of contacts holes by the number of contact holes,
and the reference data storage unit also adapted to store (c) a reference value of an average surface area of underlying substrate exposed by a contact hole in the sample substrate.

10. The apparatus of claim 1, wherein the contact hole in the test substrate and the contact hole in the sample substrate each have a substantially circular configuration,
reference data (b) includes a diameter of underlying substrate exposed by the contact hole in the sample substrate, and
the calculating device calculates a diameter of underlying substrate exposed by the contact hole in the test substrate.

11. The apparatus of claim 1, wherein the material layer of the respective test substrate and sample substrate is a dielectric layer.

12. The apparatus of claim 1, wherein the material layer of the respective test substrate and sample substrate is formed of a material comprising at least one of silicon oxide (SiO₂), silicon nitride (SiN), aluminum oxide (Al₂O₃), and hafnium oxide (HfO₂).

13. A substrate contact hole measuring apparatus, comprising:
an electron irradiator for irradiating an electron beam onto a test substrate having a contact hole formed in a material layer;
a reference data storage unit adapted to store (a) reference data that comprises current flow measured over an elapsed time in a sample substrate defining a contact hole of known characteristics formed in a material layer that has been irradiated with an electron beam, and (b) reference data that comprises a property value of the contact hole including a surface area of underlying substrate exposed by the contact hole;
a current measuring device adapted to measure current flow in the test substrate;
a calculating device adapted to calculate a property value of the contact hole in the test substrate including a surface area of underlying substrate exposed by the contact hole in the test substrate using the measured current flow in the test substrate and the reference data (a) and (b) from the sample substrate;
a scanning electron microscope (SEM) for measuring an inlet area of the contact hole in the test substrate; and
a comparator adapted to compare the inlet area of the contact hole in the test substrate with the calculated surface area of underlying substrate exposed by the contact hole in the test substrate.

14. The apparatus of claim 13, wherein the reference data (b) includes a graphical representation of the current flow in the sample substrate.

15. The apparatus of claim 13, wherein the reference data (b) includes a convergence value of the current flow in the sample substrate, an extreme value of the current flow in the sample substrate, and a graphical representation of the current flow in the sample substrate prior to convergence of the current flow.

16. The apparatus of claim 13, wherein the material layer of the respective test substrate and sample substrate is formed of a material comprising at least one of silicon oxide (SiO₂), silicon nitride (SiN), aluminum oxide (Al₂O₃), and hafnium oxide (HfO₂).

17. A substrate contact hole measuring apparatus, comprising:
an electron irradiator for irradiating an electron beam onto a test substrate having a contact hole formed in a material layer;
a reference data storage unit adapted to store (a) reference data that comprises current flow measured over an elapsed time in a sample substrate defining a contact hole of known characteristics formed in a material layer that has been irradiated with an electron beam, and
(b) reference data that comprises a property value of the contact hole including a surface area of underlying substrate exposed by the contact hole;
a current measuring device adapted to measure current flow in the test substrate;
a calculating device adapted to calculate a property value of the contact hole in the test substrate including a surface area of underlying substrate exposed by the contact hole in the test substrate using the measured current flow in the test substrate and the reference data (a) and (b) from the sample substrate;
an estimated area storage unit adapted to store an estimated area of a surface of underlying substrate exposed by the contact hole in the test substrate; and
a comparator adapted to compare the estimated area with the calculated surface area of underlying substrate exposed by the contact hole in the test substrate.

18. The apparatus of claim 17, wherein the reference data (b) includes a graphical representation of the current flow in the sample substrate.

19. The apparatus of claim 17, wherein the reference data (b) includes a convergence value of the current flow in the sample substrate, an extreme value of the current flow in the sample substrate, and a graphical representation of the current flow in the sample substrate prior to convergence of the current flow.

20. The apparatus of claim 17, wherein the material layer of the respective test substrate and sample substrate is formed of a material comprising at least one of silicon oxide (SiO₂), silicon nitride (SiN), aluminum oxide (Al₂O₃), and hafnium oxide (HfO₂).

21. A method of measuring a property value of a contact hole formed in a material layer of a test substrate, the method comprising:
irradiating electrons to a sample substrate defining a contact hole of known characteristics formed in a material layer;
measuring current flow in the sample substrate; and
storing reference data comprising (a) reference data comprising measured current flow in the sample substrate and (b) reference data comprising a property value of the contact hole;
irradiating electrons to the test substrate;
measuring current flow in the test substrate;
calculating a property value of the contact hole in the test substrate based on the current flow measured in the test substrate and the stored reference data (a) and (b),
wherein the calculated property value of the contact hole in the test substrate includes a surface area of underlying substrate exposed by the contact hole in the test substrate.

22. The method of claim 21, wherein measuring the current flow in the sample substrate includes measuring the current flow over an elapsed time.

23. The method of claim 22, wherein the reference data (b) includes a graphical representation of the current flow in the sample substrate.

24. The method of claim 22, wherein the reference data (b) includes a convergence value of the current flow in the sample substrate, an extreme value of the current flow in the sample substrate, and a graphical representation of the current flow in the sample substrate prior to convergence of current flow.

25. The method of claim 21, wherein the reference data (b) includes a diameter of underlying substrate exposed by the contact hole in the sample substrate, and the calculated property value of the contact hole in the test substrate includes a diameter of underlying substrate exposed by the contact hole.

26. The method of claim 21, further comprising:
measuring an inlet area of the contact hole in the test substrate with a scanning electron microscope (SEM); and
comparing the inlet area of the contact hole in the test substrate with the calculated surface area of underlying substrate exposed by the contact hole.

27. The method of claim 21, further comprising:
irradiating electrons to an area of the sample substrate defined by a plurality of contact holes;
storing reference data (c) comprising an average surface area of underlying substrate exposed per contact hole in the irradiated area of the sample substrate;
irradiating a test area of the test substrate defined by a plurality of contact holes;
scanning the test area of the test substrate with a scanning electron microscope (SEM);
measuring a sum of surface areas of underlying substrate exposed by the plurality of contact holes in the test area with the SEM; and
calculating an average surface area of underlying substrate exposed per contact hole in the test area by dividing the sum of the exposed surface areas in the test area by the number of contact holes in the test area.

28. The method of claim 21, further comprising comparing an estimated surface area of underlying substrate exposed by the contact hole in the test substrate with the calculated surface area of underlying substrate exposed by the contact hole in the test substrate.
